(19) United States
(12) Patent Application Publication
(10) Pub. No.: US 2025/0313938 A1
(43) Pub. Date: Oct. 9, 2025

(54) VAPOR DEPOSITION MASK, MANUFACTURING METHOD OF VAPOR DEPOSITION MASK, AND MANUFACTURING METHOD OF LIGHT EMITTING DEVICE

(71) Applicant: CANON KABUSHIKI KAISHA, Tokyo (JP)

(72) Inventors: SHINICHIRO WATANABE, Kanagawa (JP); YOUICHI FUKAYA, Tokyo (JP)

(21) Appl. No.: 19/090,628

(22) Filed: Mar. 26, 2025

(30) Foreign Application Priority Data
Apr. 4, 2024 (JP) 2024-060969

(51) Int. Cl. C23C 14/04; H10K 71/16

(52) U.S. Cl. CPC C23C 14/042; H10K 71/166

(57) ABSTRACT

A vapor deposition mask is provided. The vapor deposition mask includes: a base material provided with a plurality of openings; and a material layer that includes a first portion arranged on an inner wall of the base material facing one of the plurality of openings, and contains a material different from the base material. The material layer has a concave-convex shape in the first portion.

### BACKGROUND OF THE INVENTION

### Field of the Invention

The present disclosure relates to a vapor deposition mask, a manufacturing method of the vapor deposition mask, and a manufacturing method of a light emitting device.

### Description of the Related Art

A light emitting device including a light emitting element using an organic electroluminescence (EL) element is known. Japanese Patent Laid-Open No. 2022-184708 describes a vapor deposition mask in which a concave-convex shape is provided in an inner wall facing each opening for passing vapor deposition particles. When forming a material film on a vapor deposition target substrate, material particles having reached the inner wall of the opening of the vapor deposition mask are stably deposited on the inner wall while being supported by protruding portions constituting the concave-convex shape. Therefore, it is suppressed that the vapor deposition film deposited on the inner wall peels off and adheres to the vapor deposition target substrate as a foreign substance.

### SUMMARY OF THE INVENTION

To implement a high-definition light emitting device, it is necessary to implement a high-definition vapor deposition mask used in the manufacture of the light emitting device. On the other hand, since the manufacturing cost of the high-definition vapor deposition mask is high, repeated use of the vapor deposition mask is desirable. Repeated use of a vapor deposition mask means that, after vapor deposition of a material film, the material film deposited on the vapor deposition mask is removed from the vapor deposition mask and the vapor deposition mask is reused. In the arrangement described in Japanese Patent Laid-Open No. 2022-184708, when removing the material film deposited on the vapor deposition mask from the vapor deposition mask, a part of the material film may remain on the protruding portion. If the vapor deposition mask with the remaining material film is reused, a material film is further deposited on the remaining material film, and a locally thickened abnormal growth portion can be formed. The abnormal growth portion may prevent the passage of the deposition particles, and may become a source of particles, thereby causing a pattern failure of the material film formed on the vapor deposition target substrate.

Some embodiments of the present disclosure provide a technique advantageous in repeated use of a vapor deposition mask.

According to some embodiments, a vapor deposition mask comprising: a base material provided with a plurality of openings; and a material layer that includes a first portion arranged on an inner wall of the base material facing one of the plurality of openings, and contains a material different from the base material, wherein the material layer has a concave-convex shape in the first portion, is provided.

According to some other embodiments, a manufacturing method of a vapor deposition mask, comprising: preparing a base material provided with a plurality of openings; forming a material layer including a first portion arranged on an inner wall of the base material facing one of the plurality of openings, and containing a material different from the base material; and forming a concave-convex shape in the first portion of the material layer, is provided.

According to still other embodiments, a manufacturing method of a light emitting device in which a plurality of pixels each including an organic layer including a light emitting layer are arranged, comprising forming the organic layer by using a vapor deposition mask provided with a plurality of openings in a base material, wherein in the vapor deposition mask, a material layer including a first portion arranged on an inner wall of the base material facing one of the plurality of openings, and containing a material different from the base material is arranged, and the material layer has a concave-convex shape in the first portion, is provided.

Further features of the present invention will become apparent from the following description of exemplary embodiments (with reference to the attached drawings).

### BRIEF DESCRIPTION OF THE DRAWINGS

FIGS. 1A to 1D are sectional views showing an example of the arrangement of a vapor deposition mask according to an embodiment;

FIGS. 2A to 2D are plan and sectional views showing the example of the arrangement of the vapor deposition mask according to the embodiment;

FIG. 3 is a sectional view showing the example of the arrangement of the vapor deposition mask according to the embodiment;

FIG. 4 is a sectional view showing an example of the arrangement of the vapor deposition mask according to the embodiment;

FIGS. 5A and 5B are sectional views showing a vapor deposition mask of a comparative example;

FIGS. 6A to 6D are sectional views showing the vapor deposition mask of the comparative example;

FIGS. 7A and 7B are sectional views showing an example of the arrangement of a pixel of a light emitting device manufactured using the vapor deposition mask according to the embodiment;

FIGS. 8A to 8C are views showing an example of an image forming device using the light emitting device shown in FIGS. 7A and 7B;

FIG. 9 is a view showing an example of a display device using the light emitting device shown in FIGS. 7A and 7B;

FIG. 10 is a view showing an example of a photoelectric conversion device using the light emitting device shown in FIGS. 7A and 7B;

FIG. 11 is a view showing an example of an electronic apparatus using the light emitting device shown in FIGS. 7A and 7B;

FIGS. 12A and 12B are views each showing an example of a display device using the light emitting device shown in FIGS. 7A and 7B;

FIG. 13 is a view showing an example of an illumination device using the light emitting device shown in FIGS. 7A and 7B;

FIG. 14 is a view showing an example of a moving body using the light emitting device shown in FIGS. 7A and 7B; and

FIGS. 15A and 15B are views each showing an example of a wearable device using the light emitting device shown in FIGS. 7A and 7B.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

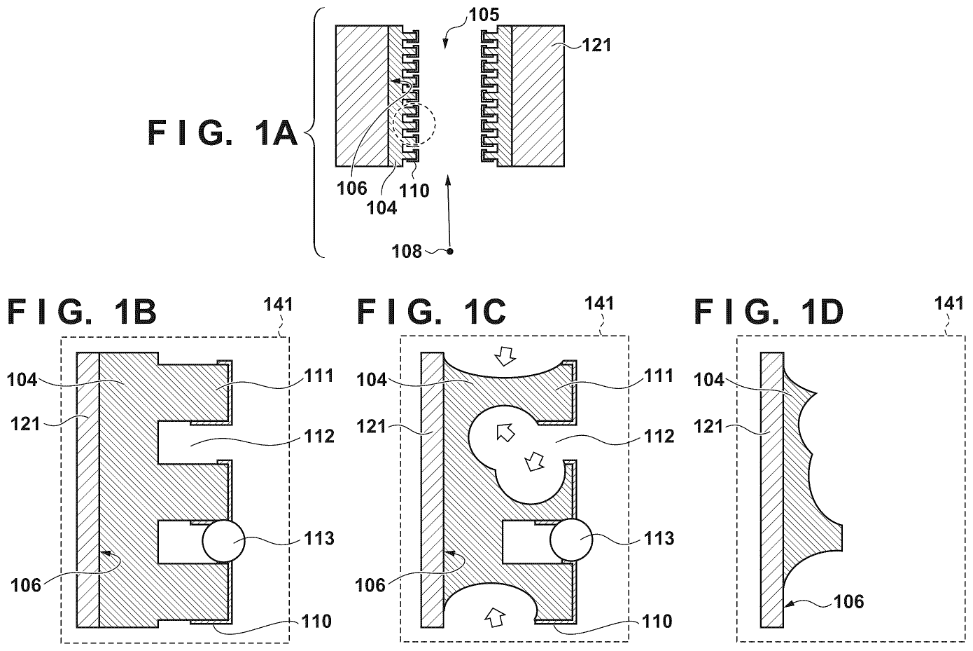

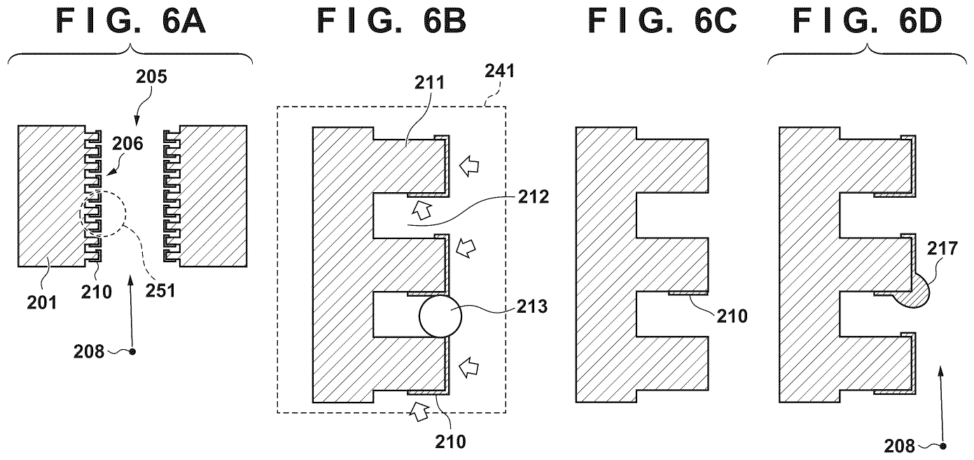

With reference to FIGS. 1A to 6D, a vapor deposition mask according to an embodiment of the present disclosure will be described. First, with reference to FIGS. 5A to 6D, problems associated with repeated use of a vapor deposition mask of a comparative example will be described. Then, a vapor deposition mask according to the embodiment will be described. Here, repeated use of a vapor deposition mask means that, after vapor deposition of a material film, for example, several to several tens of times, the material film deposited on the vapor deposition mask is removed from the vapor deposition mask and the vapor deposition mask is reused.

To implement a high-definition light emitting device including a light emitting element using an organic electroluminescence (EL) element, it is necessary to implement a high-definition vapor deposition mask used in the manufacture of the light emitting device. Vapor deposition using a vapor deposition mask is used for deposition (formation) of an organic layer including light emitting layers of a plurality of pixels arranged in the light emitting device. As the resolution of the pixel (light emitting elements) of the light emitting devices has been improved, the area where the vapor deposition material constituting the organic layer is separately applied become finer. For example, a vapor deposition mask with an opening size of about several μm corresponding to the pixel is required. As such a vapor deposition mask provided with fine openings of several μm, for example, a semiconductor substrate made of silicon or the like processed using a semiconductor process is used. By using the semiconductor process, it is possible to accurately process the semiconductor substrate to manufacture the vapor deposition mask. However, in a case of using the semiconductor process, the manufacturing cost per vapor deposition mask is high. Therefore, a repeatedly usable vapor deposition mask is needed.

FIGS. 5A and 5B are sectional views of a vapor deposition mask 201 of a comparative example manufactured by processing single-crystal silicon. FIG. 5B is an enlarged view of a portion 250 of the vapor deposition mask 201 shown in FIG. 5A. The vapor deposition mask 201 is provided with a plurality of openings 205 for passing vapor deposition particles 208. As shown in FIGS. 5A and 5B, the vapor deposition particle 208 enters from below the vapor deposition mask 201. In other words, in the arrangement shown in FIGS. 5A and 5B, a vapor deposition source is arranged below the vapor deposition mask 201, and a vapor deposition target substrate, on which a vapor deposition material is to be deposited, is arranged above the vapor deposition mask. An inner wall 206 of the vapor deposition mask 201 facing the opening 205 has a concave-convex shape formed by processing silicon as a base material 221 of the vapor deposition mask 201.

The concave-convex shape provided in the inner wall 206 of the base material 221 of the vapor deposition mask 201 can be formed using, for example, a Bosch process. The Bosch process processes the single-crystal silicon as the base material 221 of the vapor deposition mask 201 while repeating etching and formation of a protection film. Hence, a periodic concave-convex shape is formed in the inner wall 206 facing the opening 205 of the vapor deposition mask 201.

FIG. 6A is a view showing a state in which a vapor deposition material 210 is deposited on the inner wall 206 facing the opening 205 of the vapor deposition mask 201. FIGS. 6B to 6D are enlarged views of a portion 251 shown in FIG. 6A. Some of the vapor deposition particles 208 incident on the vapor deposition mask 201 from the vapor deposition source arranged below the vapor deposition mask 201 pass through the openings 205 and are deposited on a vapor deposition target substrate arranged above the vapor deposition mask. The other vapor deposition particles 208 are deposited on the vapor deposition mask 201 such as the inner wall 206. The inner wall 206 of the vapor deposition mask 201 has the concave-convex shape. Therefore, the vapor deposition particles 208 having reached the inner wall 206 of the opening 205 of the vapor deposition mask 201 are stably deposited on the inner wall 206 while being supported by convex portions 211 constituting the concave-convex shape. As a result, it is suppressed that the vapor deposition material 210 deposited on the inner wall 206 of the vapor deposition mask 201 peels off and adheres to the vapor deposition target substrate as a foreign substance.

Here, consider a case of removing the vapor deposition material 210 deposited on the vapor deposition mask 201 and repeatedly using the vapor deposition mask 201. For example, the vapor deposition material 210 can be removed by immersing the vapor deposition mask 201 in an etchant 241 that can dissolve the vapor deposition material 210. However, during immersion of the vapor deposition mask 201 in the etchant 241, as shown in FIG. 6B, an air bubble 213 inherent in the etchant 241 may enter a concave portion 212 constituting the concave-convex shape of the inner wall 206 of the vapor deposition mask 201. If the air bubble 213 enters the concave portion 212, the etchant 241 cannot enter deep into the concave portion 212 due to the air bubble 213, so that the vapor deposition material 210 may partially remain in the concave portion 212 as shown in FIG. 6C.

If the vapor deposition mask 201 is reused with the vapor deposition material 210 remaining in the concave portion 112, as shown in FIG. 6D, the vapor deposition material 210 is further deposited on the residual vapor deposition material 210, and abnormal growth of the vapor deposition material 210 is likely to occurs. An abnormal growth portion 217 generated by abnormal growth of the vapor deposition material 210 has a locally large film thickness. Therefore, when the vapor deposition particles 208 pass the opening 205, some of the vapor deposition particles 208 are blocked so the vapor deposition material 210 may not be able to be evaporated at a desirable position of the vapor deposition target substrate. In addition, the abnormal growth portion 217 is likely to peels off because it has the locally large thickness, and the peeled film can become a foreign substance.

If the base material 221 of the vapor deposition mark 201 is processed to form a concave-convex shape in the inner wall 206 facing the opening 205 provided in the vapor deposition mask 201, during immersion in the etchant 241 for reuse of the vapor deposition mask 201, the vapor deposition material 210 is likely to remain in the concave portion 212 of the inner wall 206. Therefore, if the vapor deposition material 210 deposited on the vapor deposition mask 201 is removed and the vapor deposition mask 201 is repeatedly used, problems such as a decrease in yield in the vapor deposition step can occur. The vapor deposition mask 101 according to this embodiment for suppressing such a problem will be described below.

FIG. 1A is a view showing the vicinity of an inner wall 106 facing an opening 105 of the vapor deposition mask 101 according to this embodiment. A plurality of the openings 105 are provided in a base material 121 of the vapor deposition mask 101 to pass vapor deposition particles 108 to a vapor deposition target substrate. In this embodiment, a material layer 104 containing a material different from the base material 121 is arranged on the inner wall 106 of the base material 121 facing each of the plurality of openings 105. It can also be said that the material layer 104 has a portion covering the inner wall 106 of the base material 121. The material layer 104 can be arranged to cover the inner wall 106 of the base material 121. A portion of the material layer 104 arranged to cover the inner wall 106 of the base material 121 has a concave-convex shape, similar to the inner wall 206 of the vapor deposition mask 201 of the comparative example. Here, the inner wall 106 of the base material 121 facing the opening 105 provided in the base material 121 indicates the inner wall 106 facing the opening 105 as shown in FIG. 1A, and the inner wall 106 need not necessarily be exposed to the opening 105.

As shown in FIG. 1A, the vapor deposition particles 108 pass through the opening 105 provided in the vapor deposition mask 101, and are deposited not only on the vapor deposition target substrate but also on the vapor deposition mask 101 such as the material layer 104 having the concave-convex shape. In order to remove the vapor deposition material 110 deposited on the vapor deposition mask 101 to repeatedly use the vapor deposition mask 101, the vapor deposition mask 101 is immersed in an etchant 141 that can dissolve the vapor deposition material 110. During this, as shown in FIG. 1B, an air bubble 113 inherent in the etchant 141 may enter a concave portion 112 constituting the concave-convex shape of the material layer 104 arranged on the inner wall 106 of the base material 121 of the vapor deposition mask 101. The generation of the air bubble 113 is similar to that in the case of immersing the above-described vapor deposition mask 201 of the comparative example in the etchant 241 for reuse.

However, as shown in FIG. 1C, by immersing the vapor deposition mask 101 in the etchant 141 that can remove the material layer 104 without causing significant damage to the base material 121 of the vapor deposition mask 101, the etchant 141 gradually dissolves the material layer 104. With this, although the etchant 141 cannot enter into the concave portion 112 where the air bubble 113 exists, it can dissolve the material layer 104 from the concave portion 112 where no air bubble 113 exists. As etching progresses, as shown in FIG. 1D, it is possible to remove the vapor deposition material 110 together with the material layer 104. For example, by executing etching until the material layer 104 is entirely dissolved, the material layer 104 and the vapor deposition material 110 deposited on the material layer 104 can be completely removed.

In this embodiment, the material layer 104 having a concave-convex shape and made of a material different from the base material 121 of the vapor deposition mask 101 is formed on the surface of the base material 121 including the inner wall 106 facing the opening 105 provided in the base material 121 of the vapor deposition mask 101. Thereafter, after using the vapor deposition mask 101 for vapor deposition several to several tens of times, the vapor deposition mask 101 is immersed in the etchant 141 that can remove the material layer 104. With this, it is possible to peel off the material layer 104 from the used vapor deposition mask 101, thereby removing the material layer 104 and the vapor deposition material 110 deposited on the vapor deposition mask 101 without leaving any residue. The used vapor deposition mask 101 refers to the vapor deposition mask 101 that has been used for vapor deposition of the vapor deposition material. As a result, it is possible to provide the repeatedly usable high-definition vapor deposition mask 101 while suppressing a decrease in yield in the vapor deposition step.

Here, the etchant 141 is not limited to a solution that can remove (peel off) the material layer 104 alone. For example, if a solution causes very little damage to the vapor deposition mask 101 so that the vapor deposition mask 101 can be reused, this solution can be selected as the etchant 141. In other words, if a solution has a higher etching rate for the material layer 104 than for the base material 121, this solution can be used as the etchant 141. For example, a solution having an etching selectivity of 100 or more between the material layer 104 and the base material 121 may be used as the etchant 141. For example, the etchant 141 may have an etching selectivity of 500 or more, or 1,000 or more between the material layer 104 and the base material 121.

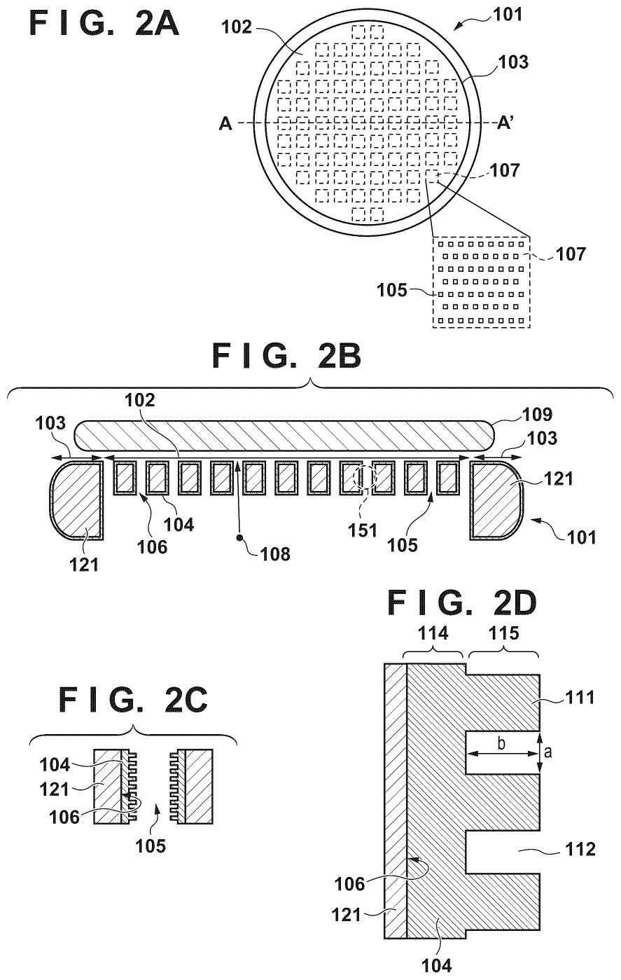

With reference to FIGS. 2A to 2D, the vapor deposition mask 101 according to this embodiment will be further described below. FIG. 2A is a plan view of the vapor deposition mask 101 according to this embodiment, and FIG. 2B is a sectional view taken along a line A-A′ in FIG. 2A. FIG. 2C is an enlarged view of a portion 151 shown in FIG. 2B, and FIG. 2D is an enlarged view of FIG. 2C for explaining the structure of the material layer 104.

The vapor deposition mask 101 according to this embodiment is formed by processing a semiconductor substrate made of single-crystal silicon or the like using a semiconductor process. The vapor deposition mask 101 can include an inner region 102 where the plurality of openings 105 (openings for pixels of the light emitting device: pixel openings) to pass the vapor deposition particles 108, and an outer region 103 surrounding the inner region 102. Depending on the semiconductor substrate to be the vapor deposition mask 101, the outer shape of the outer region 103 may have a circular shape, the outer diameter of the outer region 103 may be 100 to 300 mm, and the thickness of the outer region 103 may be 100 to 1,000 μm such as 725 μm or 775 μm. The thickness of the inner region 102 may be 1 to 100 μm. The base material 121 of the vapor deposition mask 101 is not limited to the semiconductor substrate made of single-crystal silicon or the like. A silicon on insulator (SOI) substrate may be used as the base material 121. Alternatively, for example, glass, a metal containing a magnetic material, ceramic, a resin, or the like may be used as the base material 121. The shape of the vapor deposition mask 101 is not limited to a circular shape, and may be another shape such as a rectangular shape. For example, the inner region 102 and the outer region 103 may be formed of different materials.

In the inner region 102 of the vapor deposition mask 101, for example, a plurality of pixel areas 107 each corresponding to a plurality of chips (light emitting devices) are arranged. In each pixel area 107, multiple openings 105 corresponding to each pixel of the light emitting device are arranged. The shape of the opening 105 may be a circular shape or a rectangular shape. The shape of the opening 105 can be changed in accordance with the shape of the pixel formed on the vapor deposition target substrate 109. The size of the opening 105 may be defined by the opening width or area. If the opening shape is circular, the size can be defined by the diameter length. If the opening shape is rectangular, the size can be defined by the diagonal length. For example, the width of the opening 105 can be reduced to about several μm. In the arrangement shown in FIG. 2B, the sectional shape of the opening 105 has the same opening width on the vapor deposition target substrate 109 side and on the vapor deposition source side opposite thereto, but the opening 105 may have a tapered shape with the large opening width on the vapor deposition source side.

On the surface of the vapor deposition mask 101 including the inner wall 106 facing the opening 105 of the base material 121 of the vapor deposition mask 101, the material layer 104 made of a material different from the base material 121 of the vapor deposition mask 101 and having the concave-convex shape is formed. The material layer 104 can be formed using, for example, an atomic layer deposition (ALD) method. Since the ALD method can conformally deposit the material layer 104 on the base material 121, substantially the same surface shape as the base material 121 before the deposition of the material layer 104 can be maintained. However, formation of the material layer 104 is not limited to the ALD method, and an appropriate deposition method can be selected in accordance with the shape of the vapor deposition mask 101. For example, a Chemical Vapor Deposition (CVD) method, a sputtering method, or the like may be used for the material layer 104.

FIG. 2D is an enlarged view of the material layer 104 arranged on the inner wall 106 facing the opening 105 of the base material 121 of the vapor deposition mask 101. The material layer 104 includes a region 115 and a region 114 arranged between the region 115 and the inner wall 106 of the base material 121. In this case, the region 114 and the region 115 may have different densities. More specifically, the density of the region 114 may be higher than the film density of the region 115. The ratio of the depth to the width of the concave portion 112 of the concave-convex shape of the material layer 104 may be 1 or more. That is, as shown in FIG. 2D, letting a be the width of the concave portion 112 in the region 115 and b be the depth thereof, b/a may be larger than 1. Here, the width a indicates the minimum opening width in a planar view of the concave portion 112. When the material layer 104 has the arrangement as described above, the vapor deposition particles 108 do not reach the inner wall 106 of the base material 121 or the region 114 as a continuous film, but are stuck in an intermittent film state in the region 115. Therefore, it can be easy to remove the vapor deposition material 110 deposited without leaving any residue.

To prevent the concave portion 112 in the region 115 from being blocked by the evaporated vapor deposition material 110, the depth b of the region 115 may be larger than the thickness of the vapor deposition material 110 to be evaporated, and the width a of the concave portion 112 in the region 115 may be larger than the thickness of the vapor deposition material 110. For example, the width a and depth b of the concave portion 112 in the region 115 may be, for example, 1 time or more and 50 times or less the film thickness of the vapor deposition material 110, or may be, for example, 5 times or more and 20 times or less the film thickness of the vapor deposition material 110. For example, if the vapor deposition material 110 is deposited to have a thickness of 20 nm on the vapor deposition target substrate 109, each of the width a and depth b of the concave portion 112 may be 20 nm or more and 1,000 nm or less, or may be 100 nm or more and 400 nm or less.

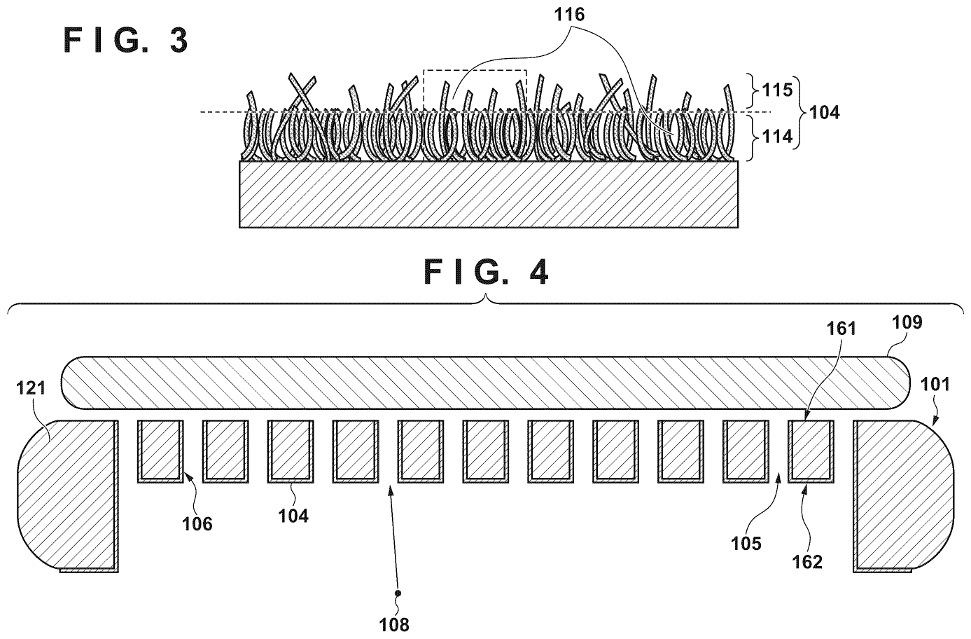

The density of each of the regions 114 and 115 described above may be defined by the amount of voids 116 in an arbitrary area (within a rectangle surrounded by dotted lines in FIG. 3) of each of the regions 114 and 115. A high density indicates a small amount of the voids 116.

The material layer 104 may be formed by, for example, a layer containing aluminum oxide crystals as a main component (a layer made of alumina hydrate) in which a concave-convex structure is formed by the aluminum oxide crystals. A method of forming the material layer 104 as described above includes, for example, the following steps. First, the base material 121 of the vapor deposition mask 101 provided with the plurality of openings 105 is prepared. In a case of newly forming the vapor deposition mask 101, the openings 105 are provided in a semiconductor substrate made of single-crystal silicon or the like using a semiconductor process or the like. In a case of, for example, repeated use of the vapor deposition mask 101, the base material 121 of the vapor deposition mask 101 provided with the plurality of openings 105 is prepared by peeling off the material layer 104 (and the vapor deposition material 110) from the used vapor deposition mask 101. Then, as the material layer 104, aluminum oxide is deposited on the surface of the base material 121 of the vapor deposition mask 101 using an ALD method. After aluminum oxide is deposited, as a step of forming a concave-convex shape, the vapor deposition mask 101 including the material layer 104 (aluminum oxide) is immersed in warm water of about 70° C. or more and 100° C. or less. Thus, the material layer 104 having a concave-convex shape can be obtained. Due to the aluminum oxide crystals (alumina hydrate) thus formed, it is possible to arbitrarily change the thickness and concave-convex shape of the material layer 104 by changing the thickness of the aluminum oxide film, the temperature of warm water, and the immersion time. For example, aluminum oxide of 100 nm is deposited on the surface of the base material 121, and immersed in warm water of 80° C. for 30 min. With this, the material layer 104 having a thickness of 400 to 500 nm and an average opening width of 100 to 200 nm can be formed.

As described in this embodiment, in a case of repeatedly using the vapor deposition mask 101 in which the base material 121 of the vapor deposition mask 101 is formed of silicon and the material layer 104 is formed of aluminum oxide (alumina hydrate), a solution containing about 3 to 4% of hydrochloric acid can be used as the etchant 141. By immersing the vapor deposition mask 101 used for vapor deposition in a solution containing hydrochloric acid for about several tens sec, it is possible to peel off the material layer 104 without damaging the base material 121 of the vapor deposition mask 101. After peeling off the material layer 104 and the vapor deposition material 110, aluminum oxide is deposited on the surface of the vapor deposition mask 101 again using the ALD method or the like, and warm water treatment is executed. Thus, the material layer 104 can be formed again. Hence, the vapor deposition mask 101 can be repeatedly used.

As described above, in this embodiment, it is possible to remove the vapor deposition material 110 deposited on the vapor deposition mask 101 without leaving any residue. As a result, it is possible to provide the high-definition vapor deposition mask 101 that can be repeatedly used for a long period of time.

In the embodiment described above, the case of the material layer 104 formed of aluminum oxide crystals (alumina hydrate) has been described, but the material used for the material layer 104 is not limited to alumina hydrate. For example, aluminum oxide, titanium oxide, or the like having a concave-convex shape (porous shape) on the surface formed by anodizing may be used as the material layer 104. For anodized aluminum oxide, a solution containing phosphoric acid or the like can be used as the etchant 141. For anodized titanium oxide, a solution containing hydrogen peroxide or the like can be used as the etchant 141. Alternatively, for example, an organic polymer having a concave-convex shape on the surface may be used as the material layer 104. In this case, an organic solvent or the like can be used as the etchant 141. By selecting the etchant 141 that does not damage the base material 121 of the vapor deposition mask 101, it is possible to remove the vapor deposition material 110 adhering to the vapor deposition mask 101 without leaving any residue. Hence, it is possible to provide the high-definition vapor deposition mask 101 that can be repeatedly used for a long period of time.

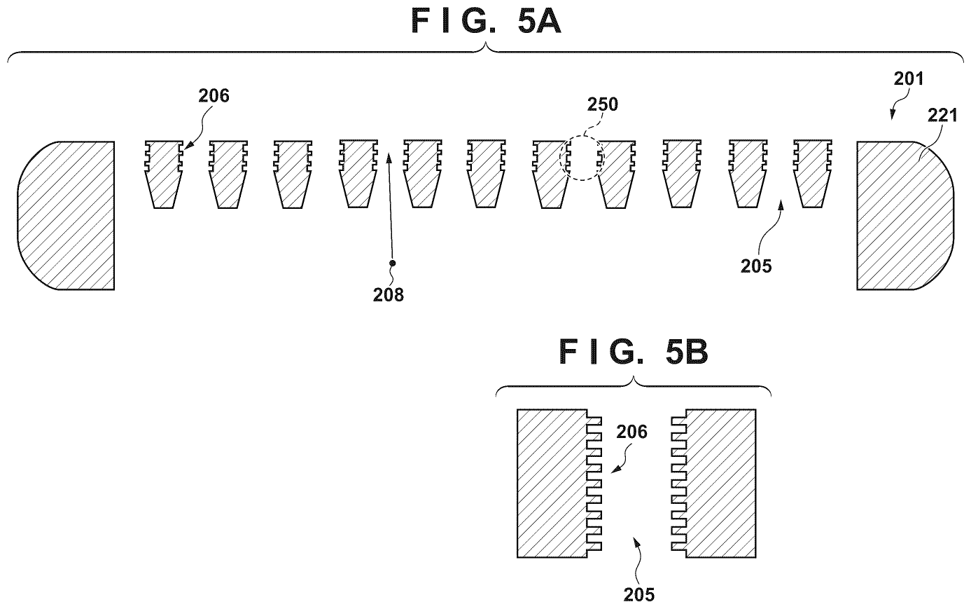

FIG. 4 is a view showing a modification of the vapor deposition mask 101 shown in FIG. 2B. As compared with FIG. 2B, the formation range of the material layer 104 is different from that in the arrangement shown in FIG. 2B.

The material layer 104 shown in FIG. 4 is formed only in the range where the vapor deposition particles 108 will be deposited on the vapor deposition mask 101. The vapor deposition mask 101 has a main surface 161 for facing the vapor deposition target substrate 109, and a main surface 162 on the opposite side of the main surface 161. In this case, the material layer 104 includes a portion that at least partially covers the main surface 162. On the other hand, the material layer 104 does not cover the main surface 161 for facing the vapor deposition target substrate 109. The material layer 104 is not formed in portions of the vapor deposition mask 101 which come into contact with the vapor deposition target substrate 109 and a jig (not shown) for fixing the vapor deposition mask 101 during vapor deposition. Accordingly, the material layer 104 of the vapor deposition mask 101 will never peel off due to contact with the vapor deposition target substrate 109, the jig, and the like. Therefore, generation of foreign substances such as particles is suppressed, and the yield in the vapor deposition step can be further improved. Although not shown in FIG. 4, a spacer layer or the like may be formed on the main surface 161 of the vapor deposition mask 101 to prevent the vapor deposition mask 101 from sticking to the vapor deposition target substrate 109. For example, fluorine resin or the like may be used as the spacer layer.

Also in the arrangement shown in FIG. 4, the material layer 104 is formed at the position where the vapor deposition material 110 will be deposited. Therefore, as in the embodiment described above, it is possible to remove the vapor deposition material 110 deposited on the vapor deposition mask 101 without leaving any residue. That is, it is possible to provide the high-definition vapor deposition mask 101 that can be repeatedly used for a long period of time.

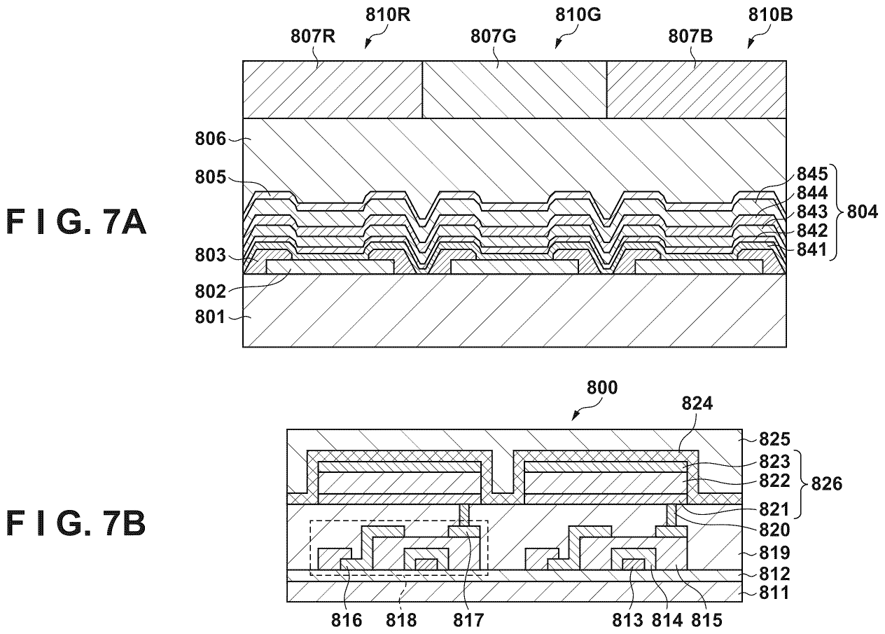

Here, a light emitting device that includes a pixel (light emitting element) including an organic layer such as a light emitting layer, which is formed using the vapor deposition mask according to this embodiment, will be described. Furthermore, application examples in which such the light emitting device is applied to an image forming device, a display device, a photoelectric conversion device, an electronic apparatus, an illumination device, a moving body, and a wearable device will be described with reference to FIGS. 7A to 15B. The description will be given assuming that, for example, an organic light emitting element (OLED) such as an organic EL element using an organic light emitting material is arranged in the pixel (to be sometimes referred to as the light emitting element, the sub-pixel, or the like) arranged in the light emitting device. Details of each component arranged in the pixel of the light emitting device will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

If the organic compound according to this embodiment is contained in the light emitting layer, the light emitting layer may be a layer made of only the organic compound according to this embodiment or a layer made of the organic metal complex according to this embodiment and another compound. Here, if the light emitting layer is a layer made of the organic metal complex according to this embodiment and another compound, the organic compound according to this embodiment may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. Note that the assist material is also called a second host. The host material can be called a first compound, and the assist material as a second compound.

If the organic compound according to an embodiment of the present disclosure is used as the guest of the light emitting layer, the concentration of the guest may be 0.01 mass % (inclusive) to 20 mass % (inclusive) relative to the entire light emitting layer, or may be 0.1 mass % (inclusive) to 10 mass % (inclusive). The guest is also called a dopant.

The organic metal complex according to this embodiment can be used as the constituent material of the organic compound layer other than the light emitting layer forming the organic light emitting element according to this embodiment. More specifically, the organic metal complex may be used as the constituent material of an electron transport layer, an electron injection layer, a hole transport layer, a hole injection layer, a hole blocking layer, or the like. In this case, the light emission color of the organic light emitting element is not limited to red. More specifically, it may be white or an intermediate color.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

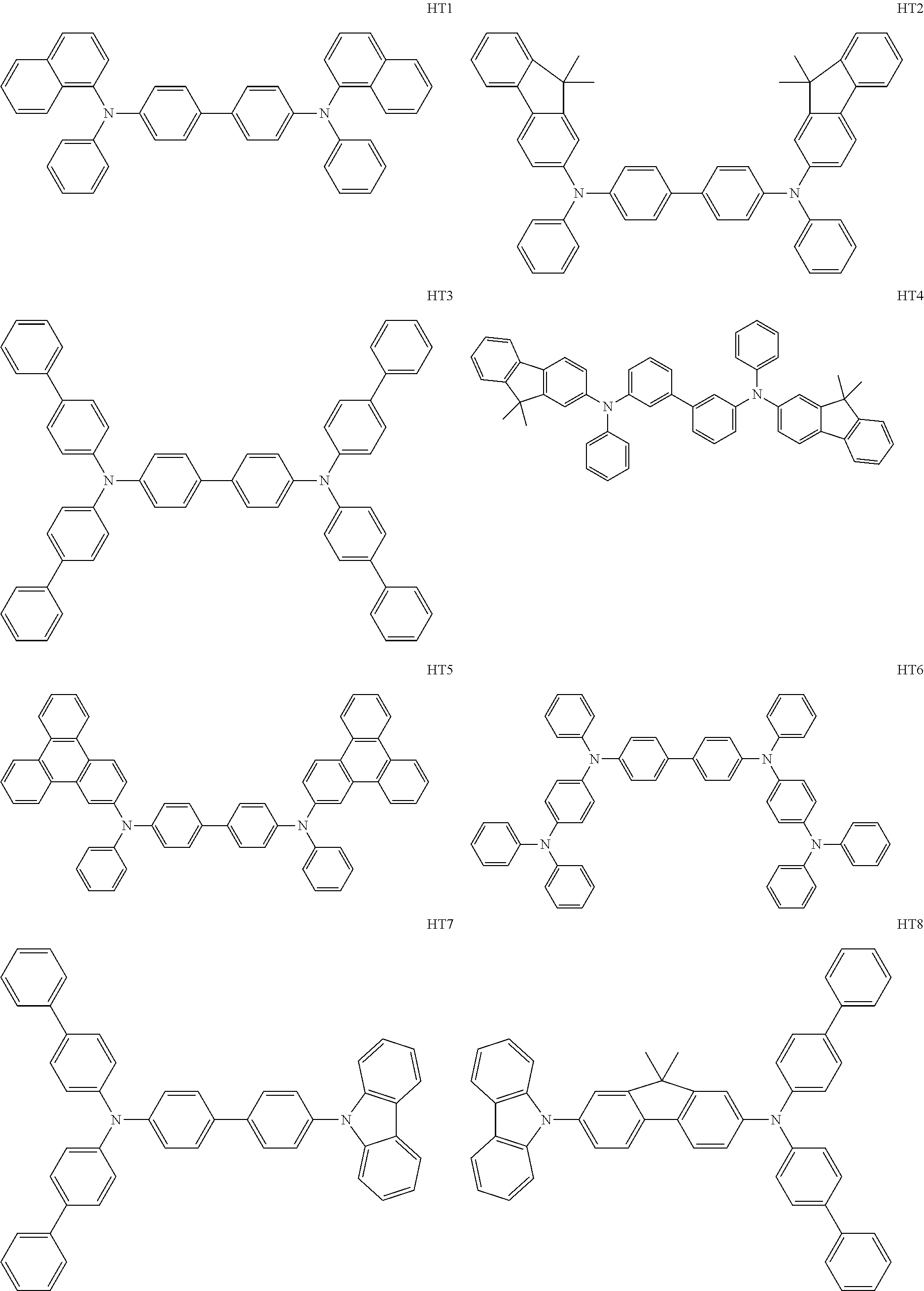

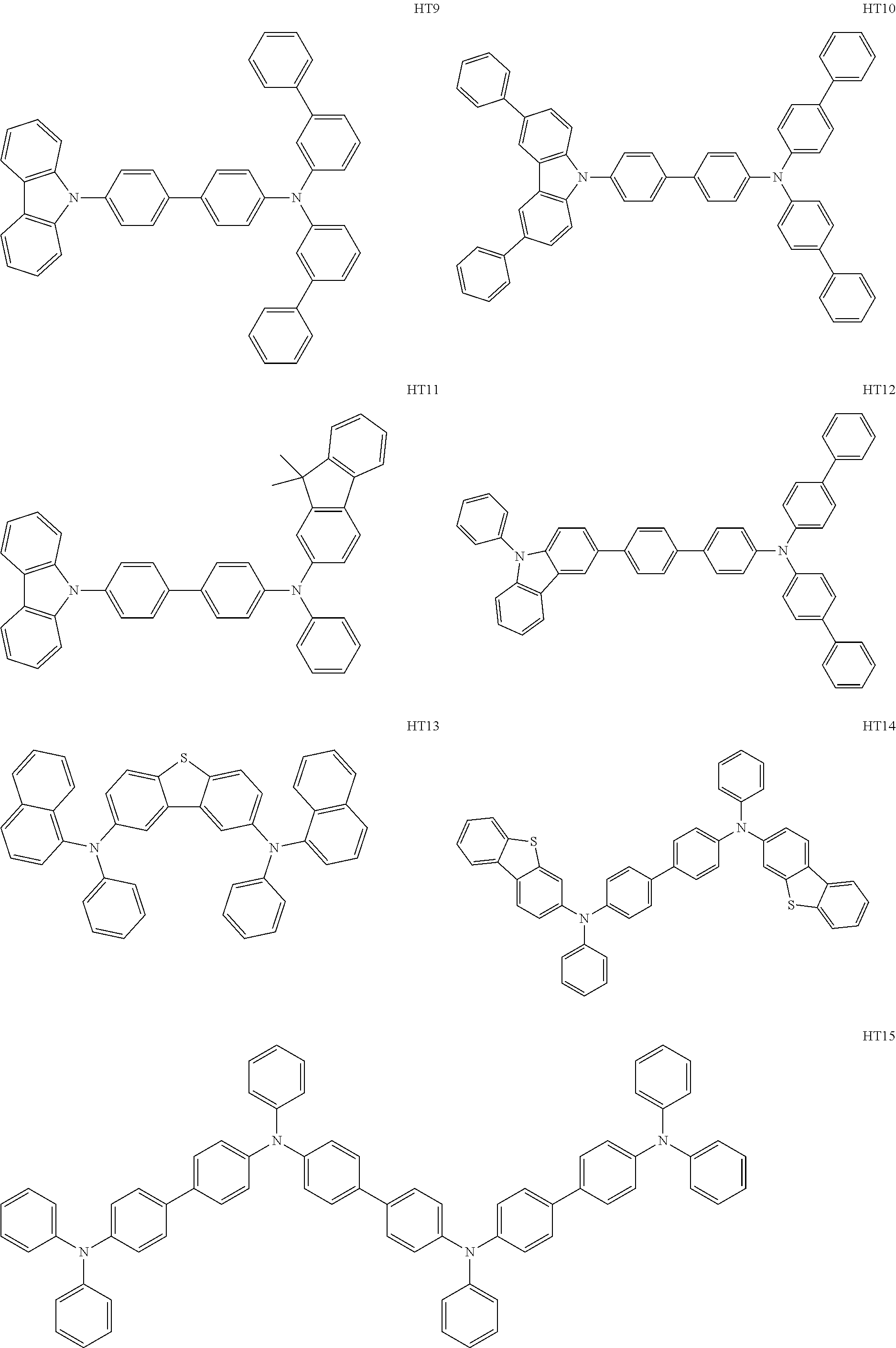

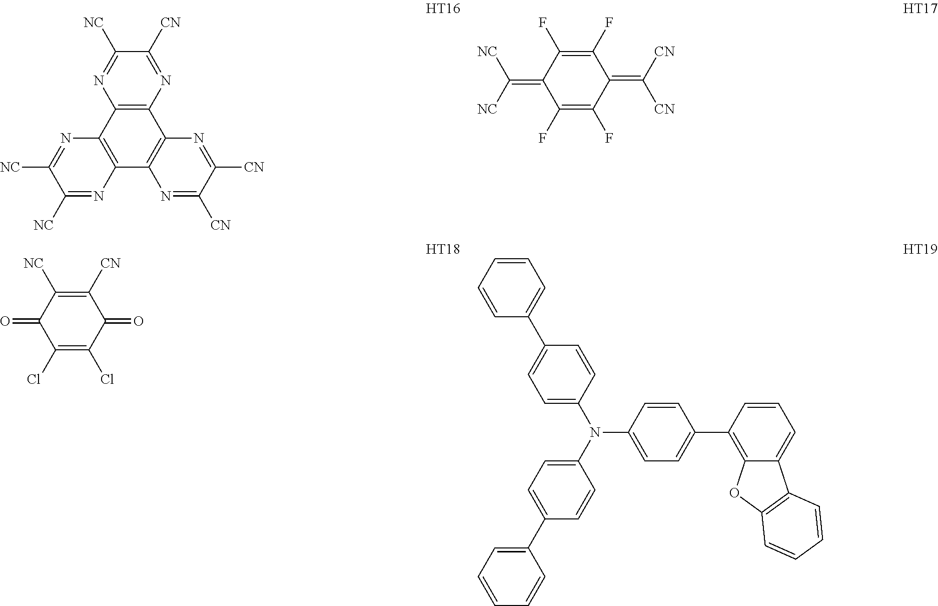

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

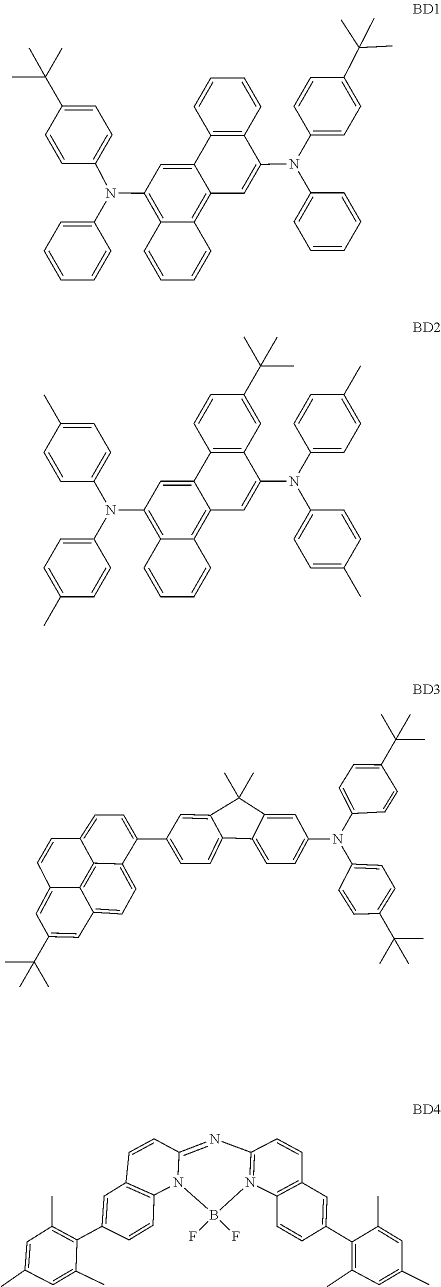

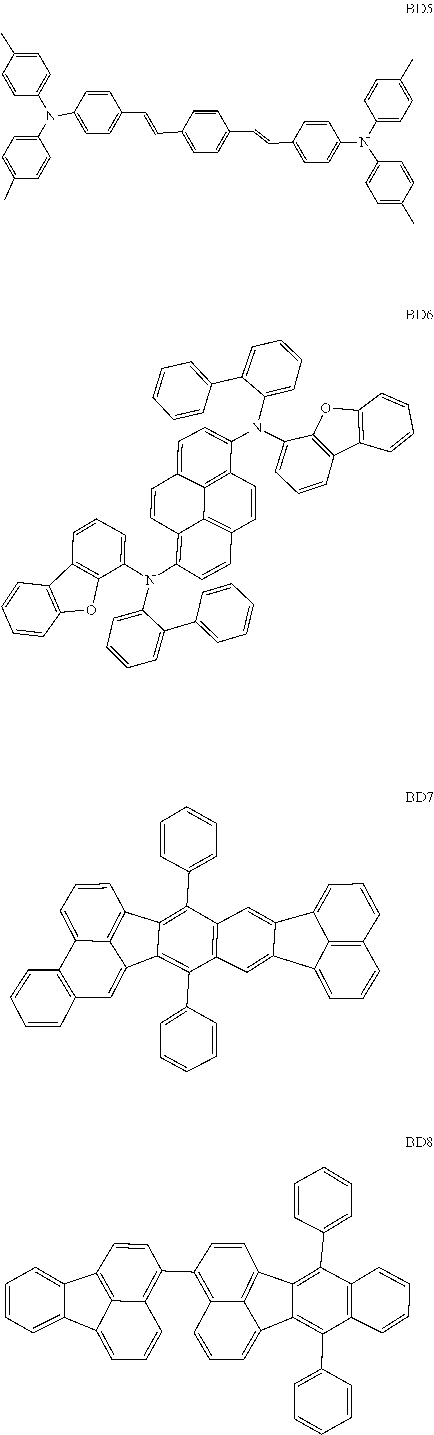

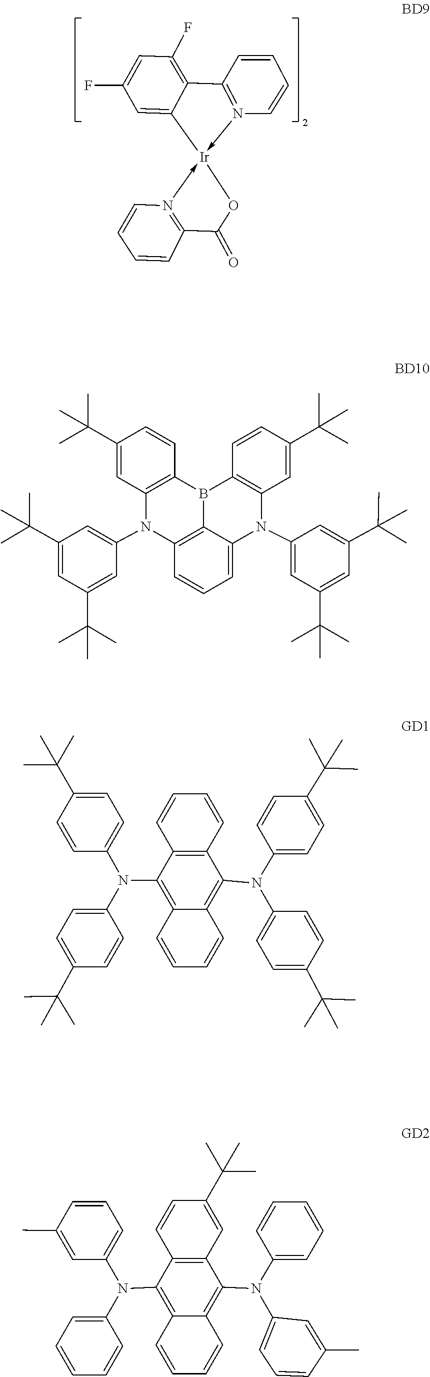

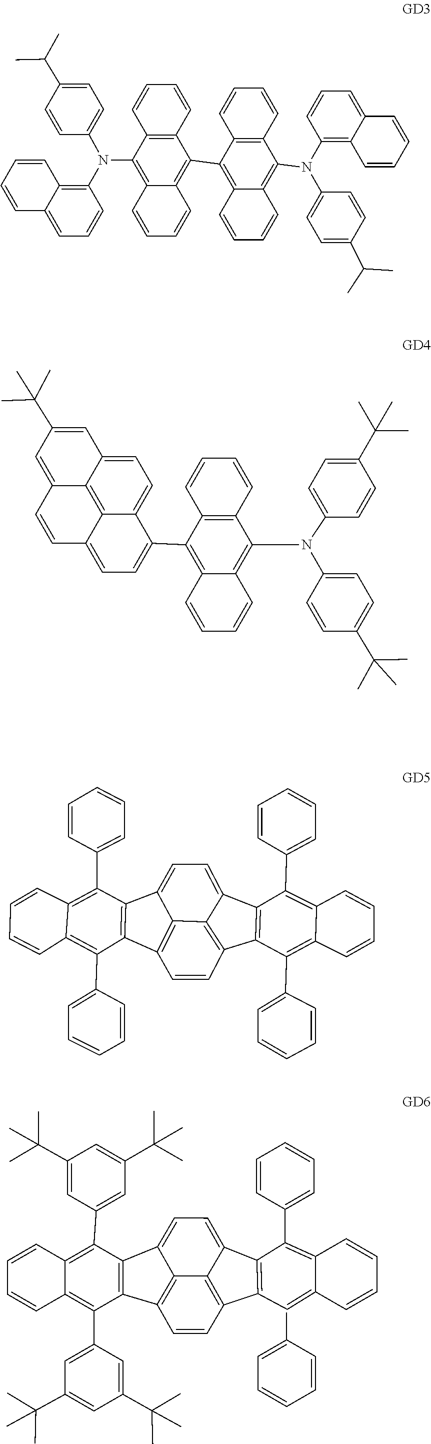

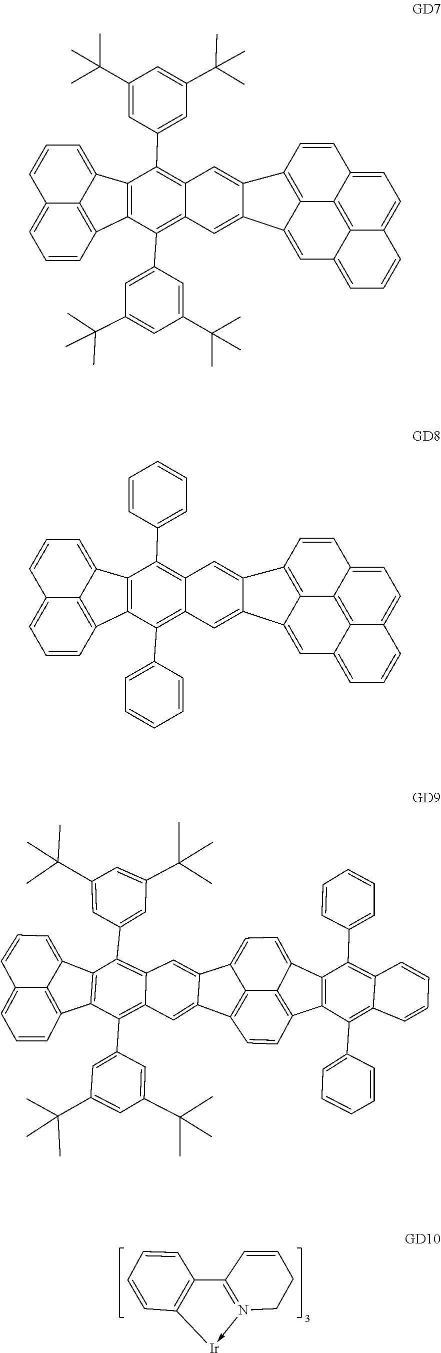

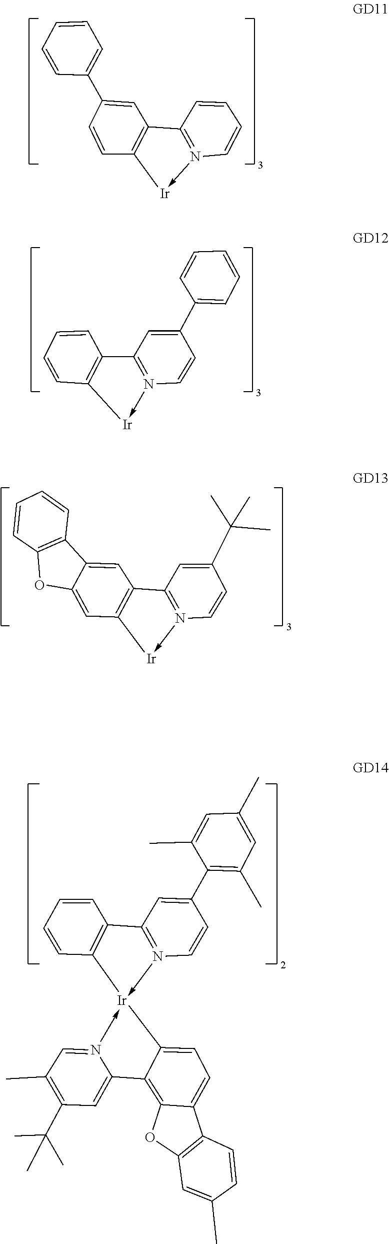

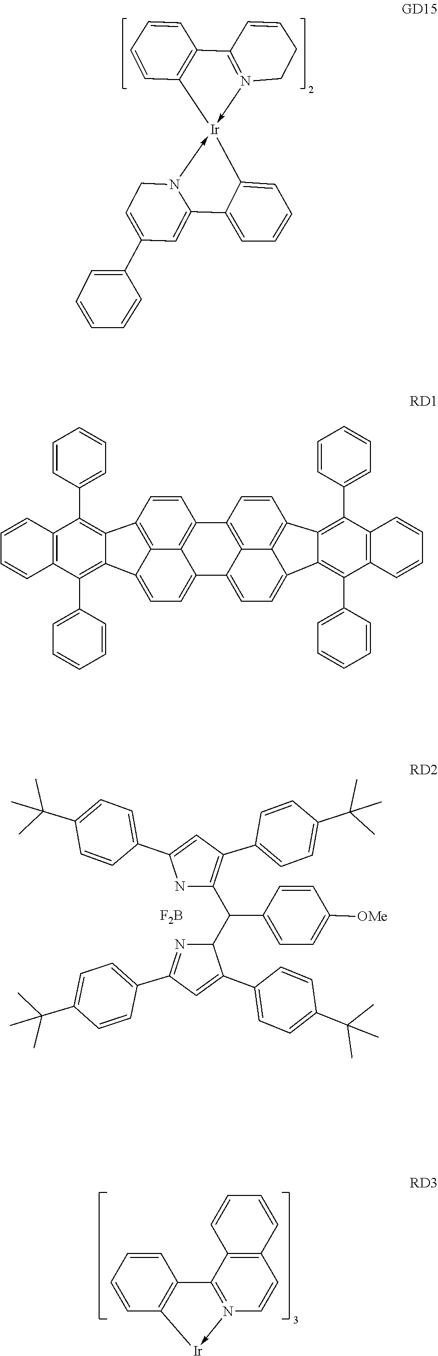

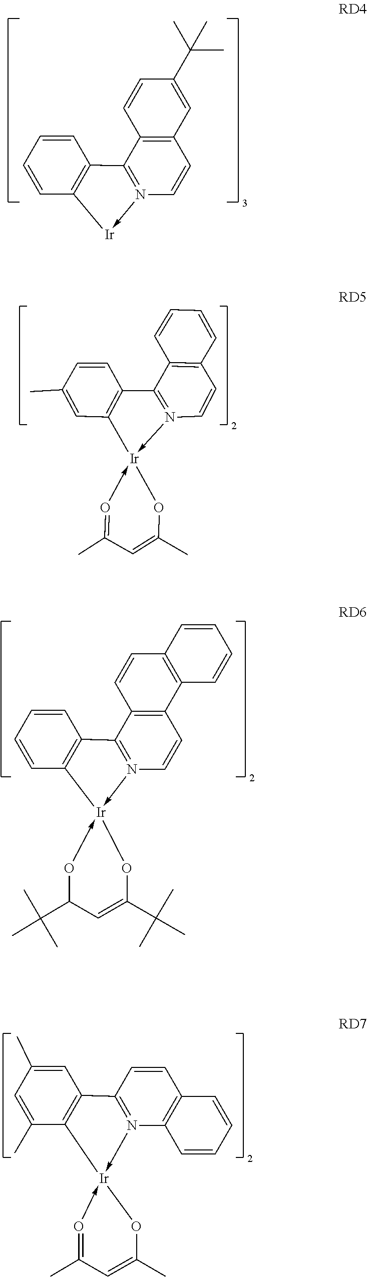

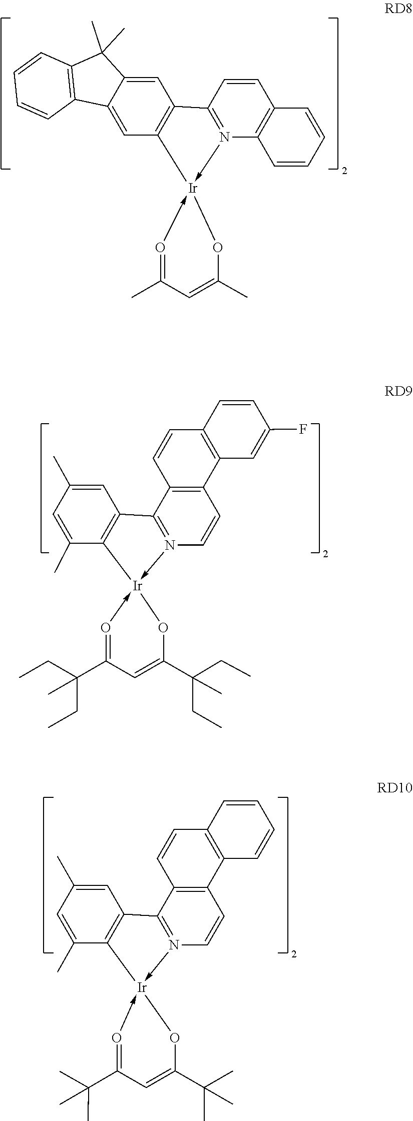

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

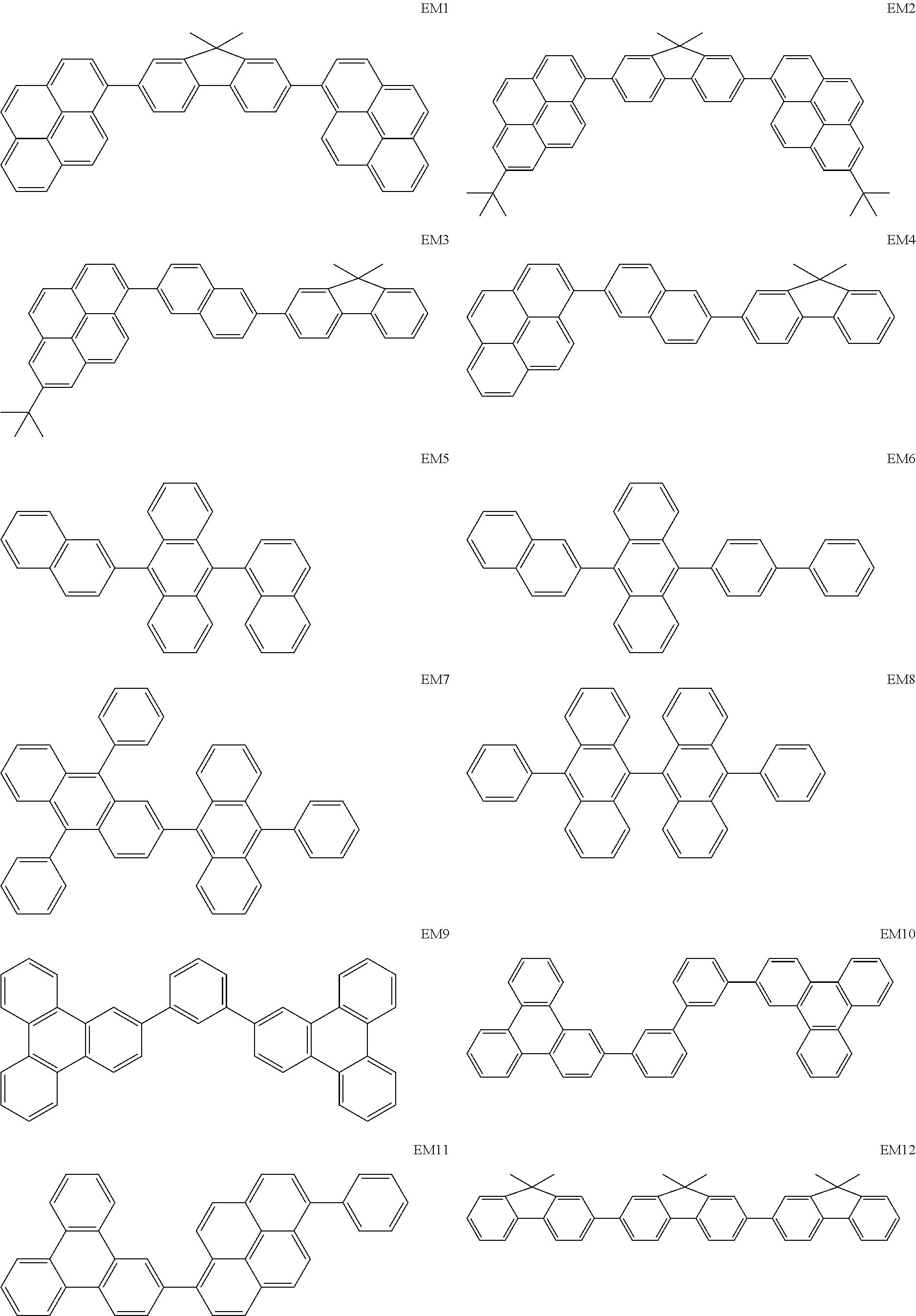

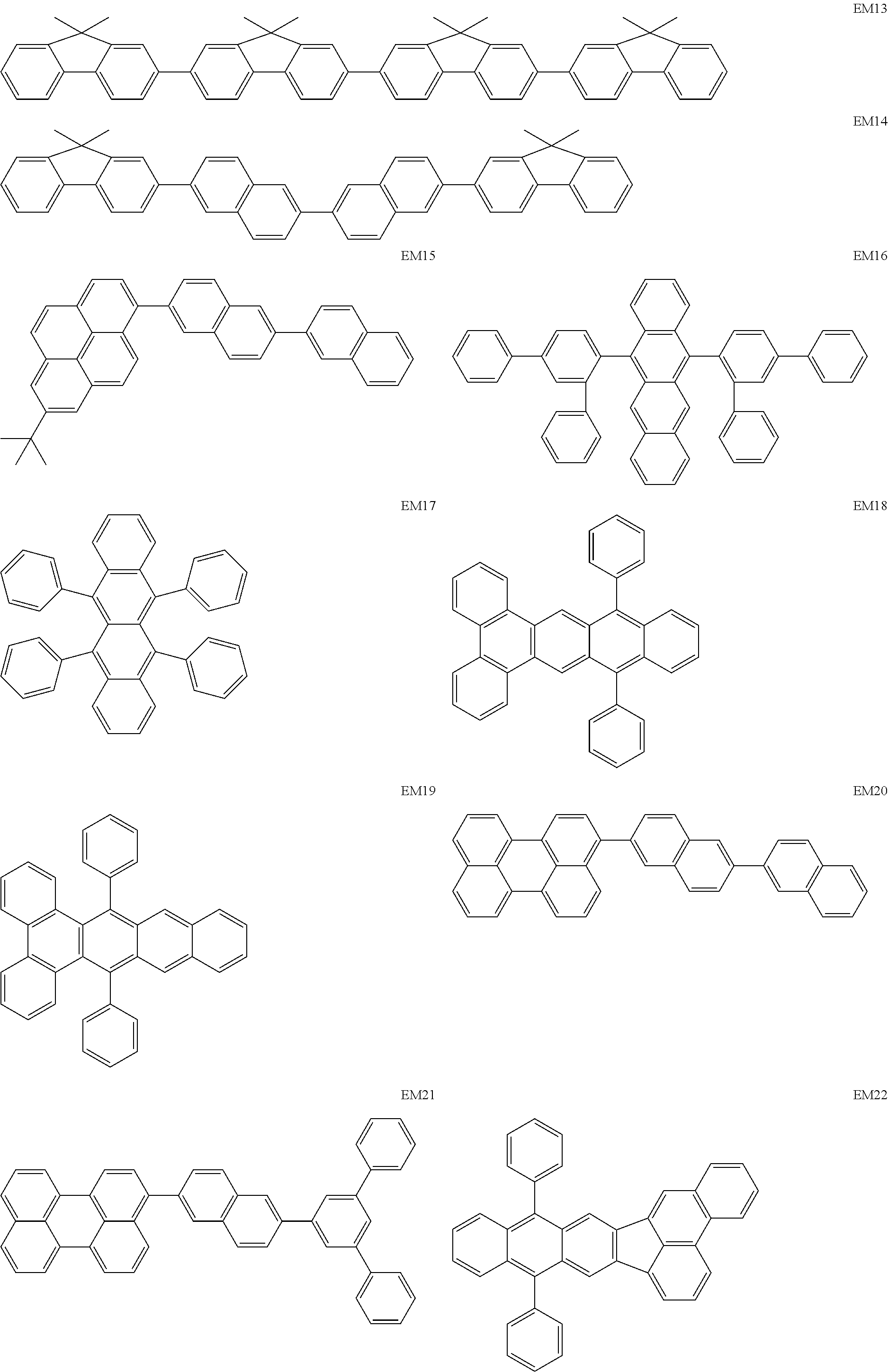

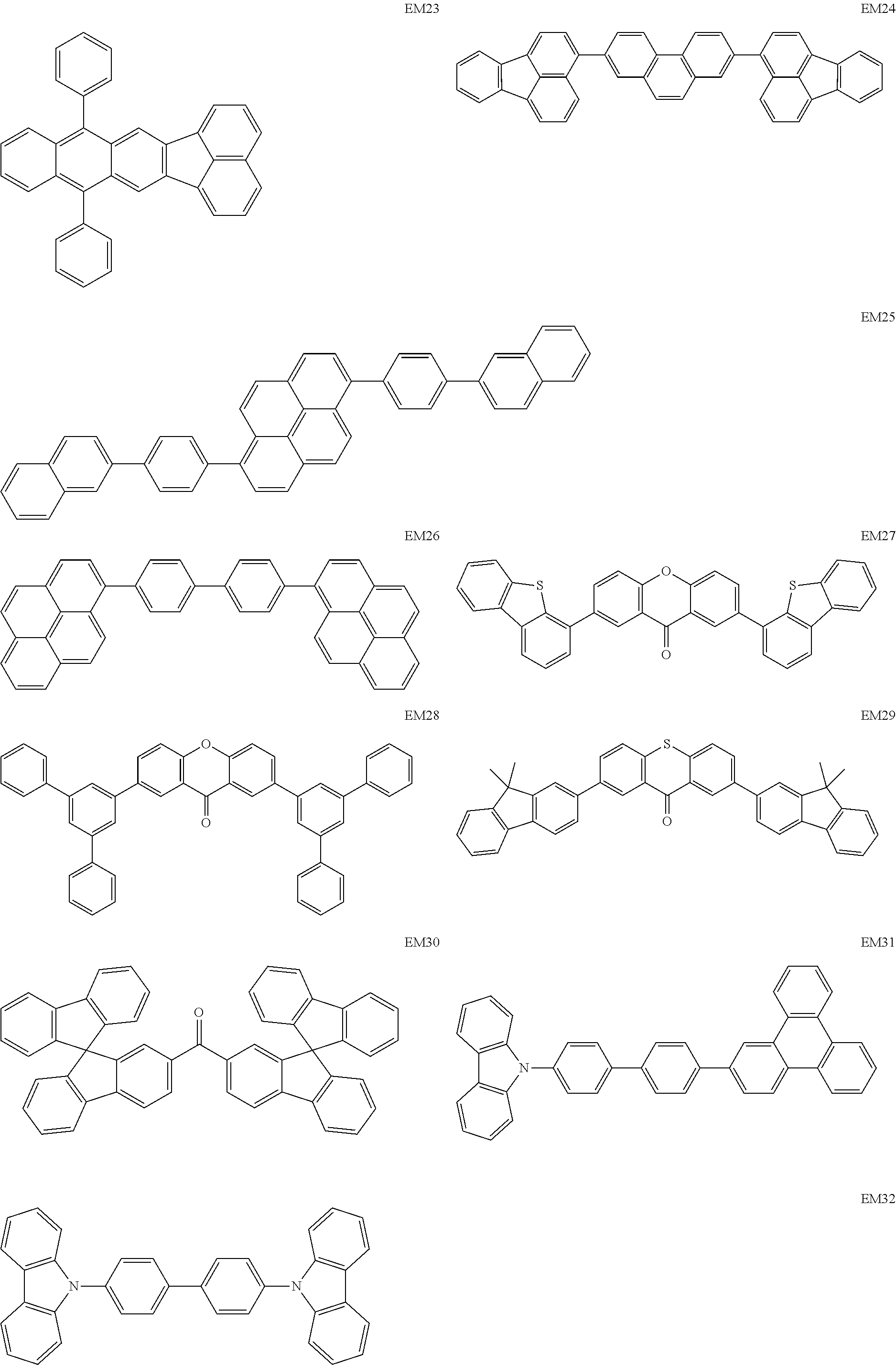

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material can also be used for the hole blocking layer as well.

Detailed examples of compounds used as the electron transport material will be shown below. The material is not limited to these.

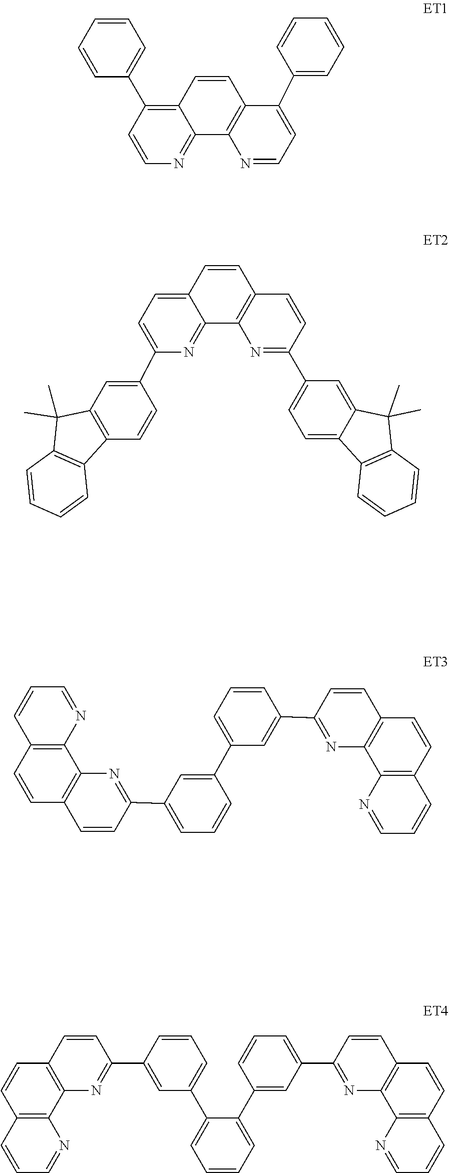

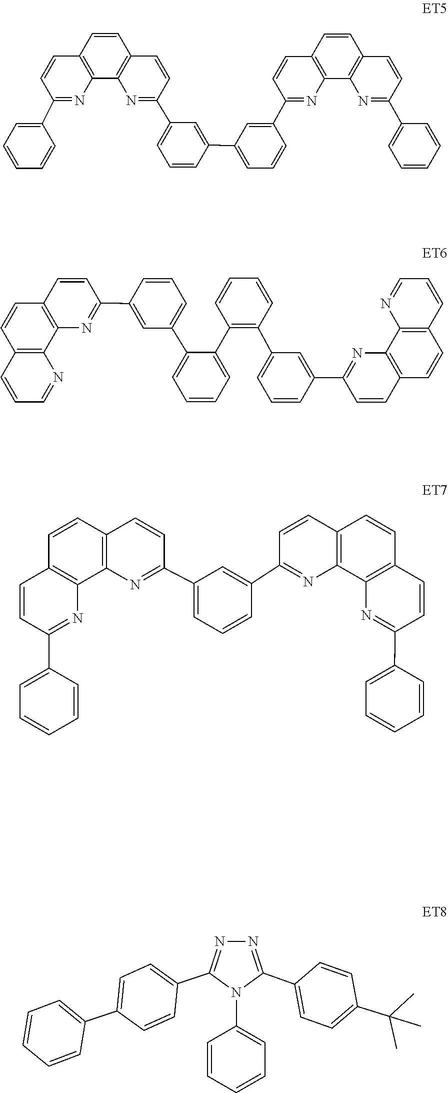 [SMILES: c1ccc(-c2ccc3ccc4ccc(-c5cccc(-c6cccc(-c7ccc8ccc9ccc(-c%10ccccc%10)nc9c8n7)c6)c5)nc4c3n2)cc1 ; c1cc(-c2ccc3ccc4cccnc4c3n2)cc(-c2ccccc2-c2ccccc2-c2cccc(-c3ccc4ccc5cccnc5c4n3)c2)c1 ; c1ccc(-c2ccc3ccc4ccc(-c5cccc(-c6ccc7ccc8ccc(-c9ccccc9)nc8c7n6)c5)nc4c3n2)cc1 ; CC(C)(C)c1ccc(-c2nnc(-c3ccc(-c4ccccc4)cc3)n2-c2ccccc2)cc1]

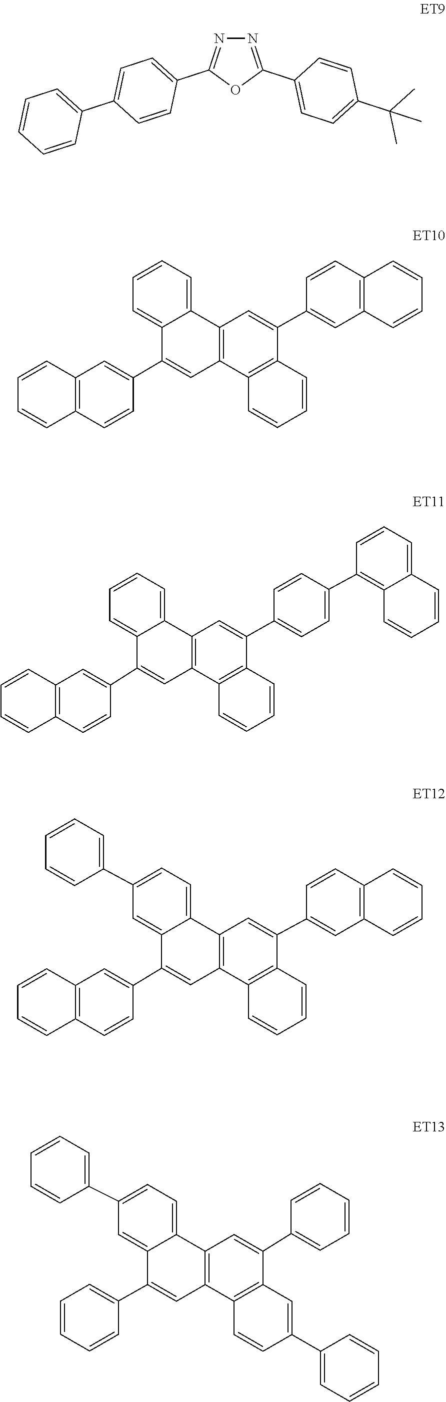

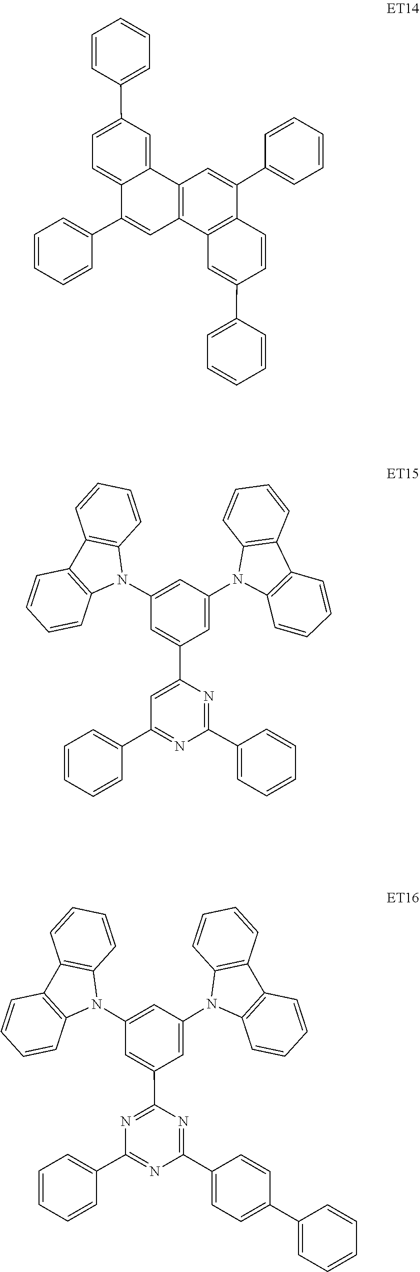

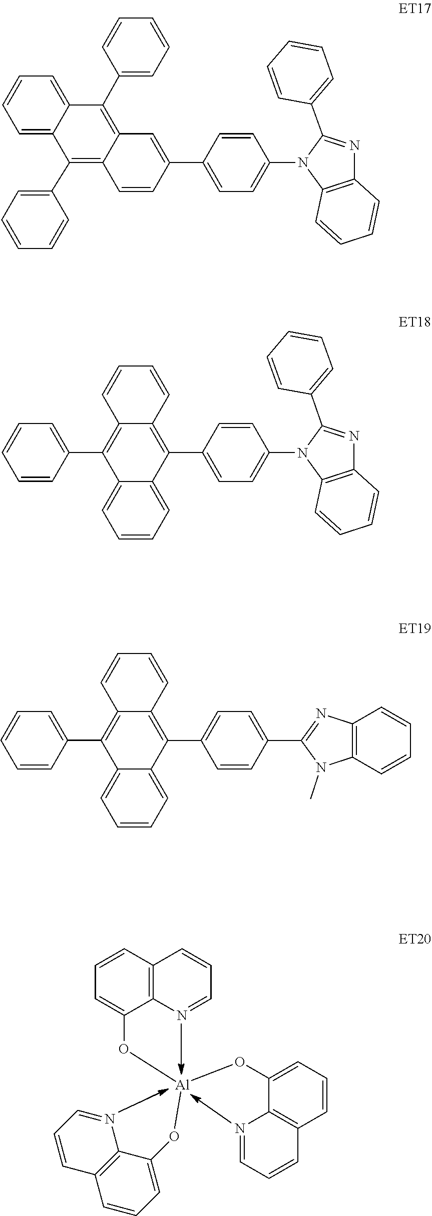

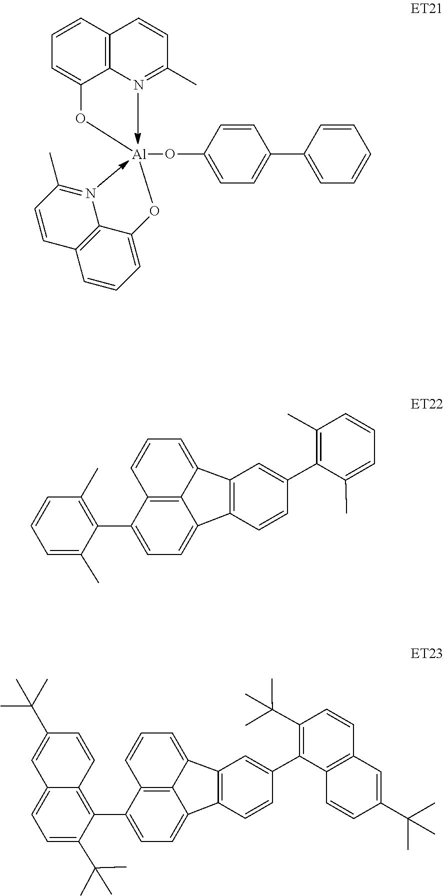

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generating portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 7A shows an example of the pixel arranged in the light emitting device. The pixel includes sub-pixels 810 (light emitting elements). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display device 800 (light emitting device) shown in FIG. 7B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 7B. That is, one of the anode and cathode and one of the source electrode and drain electrode of the TFT are electrically connected. The TFT indicates a thin-film transistor.

In the display device 800 shown in FIG. 7B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 7B, but another switching element may be used instead.

The transistor used in the display device 800 shown in FIG. 7B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 7B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

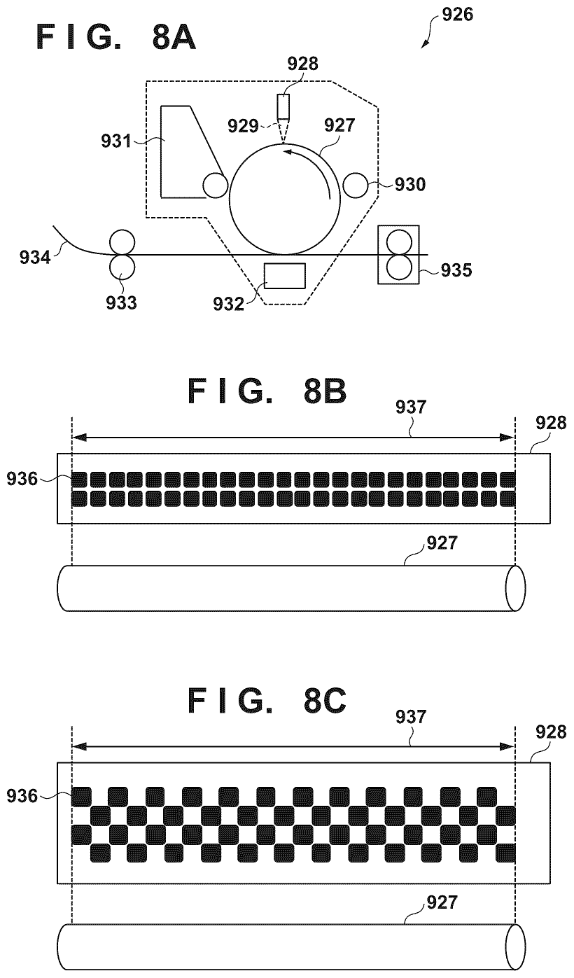

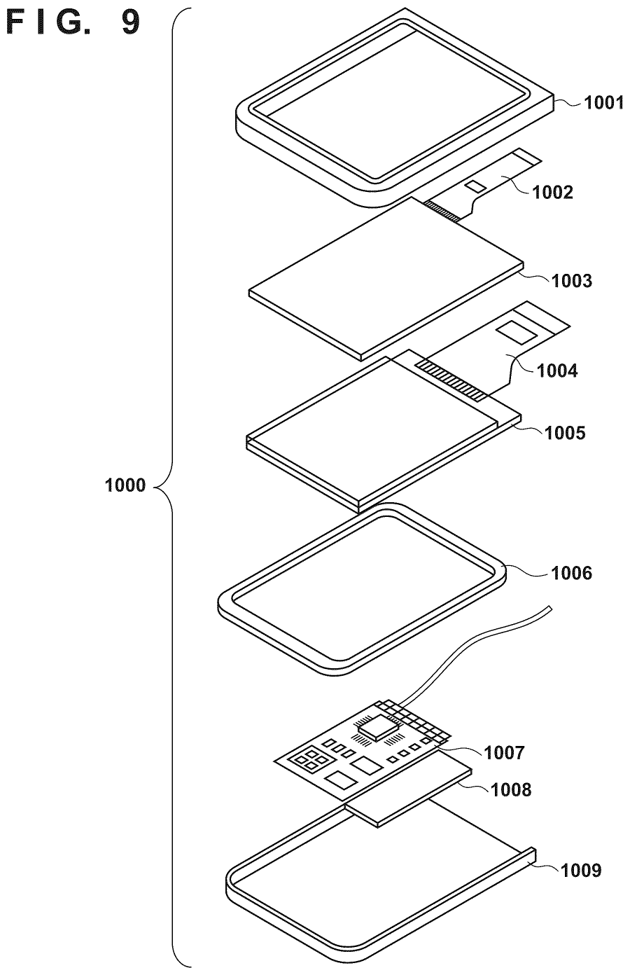

FIGS. 8A to 8C are schematic views showing an example of an image forming device using the light emitting device. An image forming device 926 shown in FIG. 8A includes a photosensitive member 927, an exposure light source 928, a developing unit 931, a charging unit 930, a transfer device 932, a conveyance unit 933 (a conveyance roller in the arrangement shown in FIG. 8A), and a fixing device 935.

Light 929 is emitted from the exposure light source 928, and an electrostatic latent image is formed on the surface of the photosensitive member 927. The light emitting device can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 8B and 8C is a schematic view showing a form in which a plurality of light emitting units 936 are arranged in the exposure light source 928 along the longitudinal direction of a long substrate. The light emitting device can be applied to each of the light emitting units 936. That is, a plurality of the pixels (light emitting elements) are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 8B shows a form in which the light emitting units 936 are arranged along the long-axis direction of the photosensitive member 927. FIG. 8C shows a form, which is a modification of the arrangement of the light emitting units 936 shown in FIG. 8B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 8C can be referred to as, for example, an arrangement in a grid pattern, an arrangement in a staggered pattern, or an arrangement in a checkered pattern.

FIG. 9 is a schematic view showing an example of the display device using the light emitting device. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. A control circuit including a logic circuit formed from transistors and the like is arranged on the circuit board 1007. The battery 1008 is unnecessary if the display device 1000 is not a portable apparatus. Even when the display device 1000 is a portable apparatus, the battery 1008 need not be provided at this position. The light emitting device can be applied to the display panel 1005. The pixels (light emitting elements) arranged in the light emitting device functioning as the display panel 1005 are connected to the control circuit arranged on the circuit board 1007 and operate.

The display device 1000 shown in FIG. 9 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

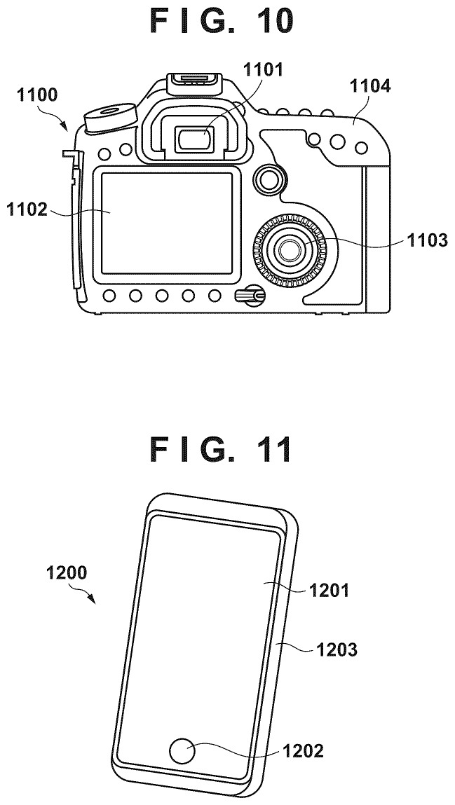

FIG. 10 is a schematic view showing an example of the photoelectric conversion device using the light emitting device. A photoelectric conversion device 1100 can include a viewfinder 1101, a rear display 1102, an operation unit 1103, and a housing 1104. The photoelectric conversion device 1100 can also be called an image capturing device. The light emitting device can be applied to the viewfinder 1101 or the rear display 1102 as a display unit. In this case, the light emitting device can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device in which the pixel (light emitting element) including the light emitting element using the organic light emitting material such as an organic EL element is arranged may be used for the viewfinder 1101 or the rear display 1102. This is so because the organic light emitting material has a high response speed. The light emitting device using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device may be applied to a display unit of an electronic apparatus. At this time, the display unit can have both a display function and an operation function. Examples of the portable terminal are a portable phone such as a smartphone, a tablet, and a head mounted display.

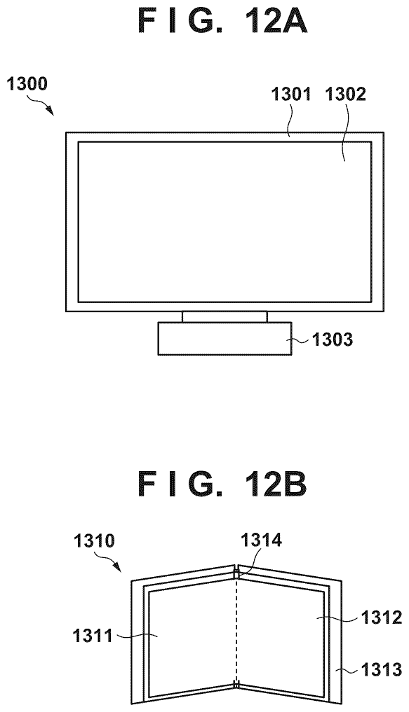

FIG. 11 is a schematic view showing an example of an electronic apparatus using the light emitting device according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device can be applied to the display unit 1201.

FIGS. 12A and 12B are schematic views showing examples of the display device using the light emitting device. FIG. 12A shows a display device such as a television monitor or a PC monitor. A display device 1300 includes a frame 1301 and a display unit 1302. The light emitting device can be applied to the display unit 1302. The display device 1300 can include a base 1303 that supports the frame 1301 and the display unit 1302. The base 1303 is not limited to the form shown in FIG. 12A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 12B is a schematic view showing another example of the display device using the light emitting device. A display device 1310 shown in FIG. 12B can be folded, and is a so-called foldable display device. The display device 1310 includes a first display unit 1311, a second display unit 1312, a housing 1313, and a bending point 1314. The light emitting device can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

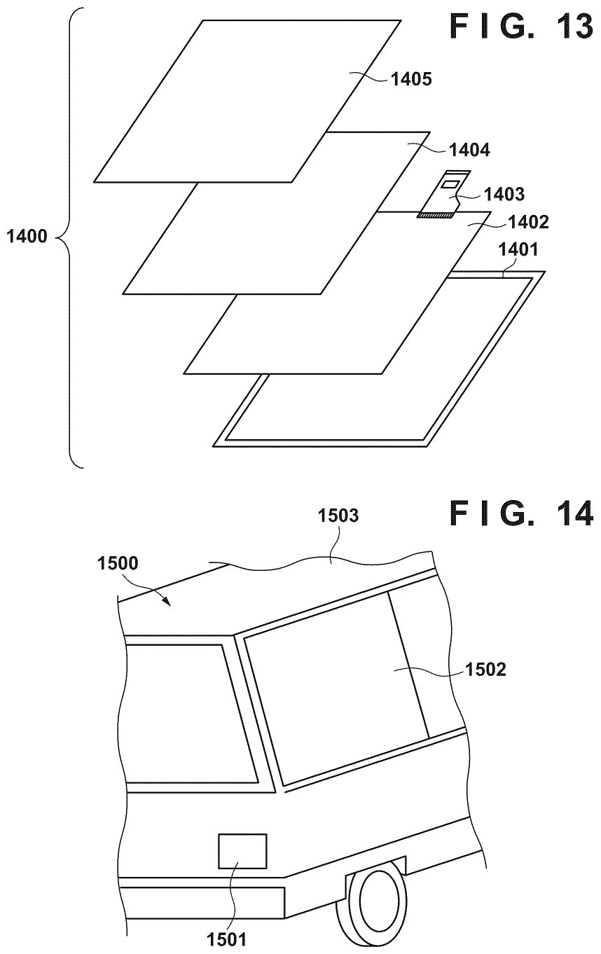

FIG. 13 is a schematic view showing an example of the illumination device using the light emitting device. An illumination device 1400 can include a housing 1401, a light source 1402, a circuit board 1403, an optical film 1404, and a light diffusing unit 1405. The light emitting device can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 14 is a schematic view of an automobile having a taillight as an example of a vehicle lighting appliance using the light emitting device. An automobile 1500 has a taillight 1501, and can have a form in which the taillight 1501 is turned on when performing a braking operation or the like. The light emitting device can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device can be applied to the taillight 1501. The taillight 1501 can include a protection member for protecting the light emitting device functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device may be used. In this case, the constituent materials of the electrodes and the like of the light emitting device are formed by transparent members.

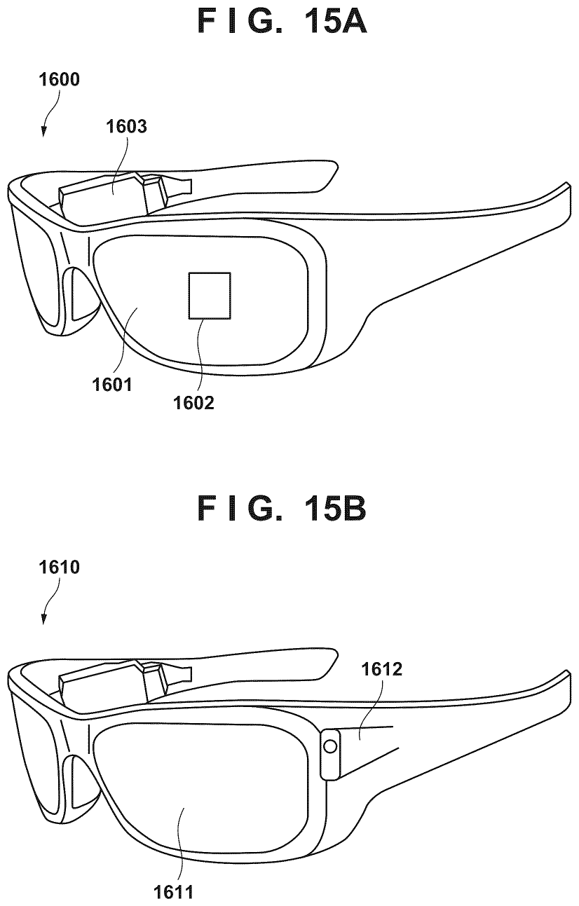

Further application examples of the light emitting device will be described with reference to FIGS. 15A and 15B. The light emitting device can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 15A. An image capturing device 1602 such as a CMOS sensor or an SPAD is provided on the surface side of a lens 1601 of the glasses 1600. In addition, the light emitting device is provided on the back surface side of the lens 1601.

The glasses 1600 further include a control device 1603. The control device 1603 functions as a power supply that supplies electric power to the image capturing device 1602 and the light emitting device. In addition, the control device 1603 controls the operations of the image capturing device 1602 and the light emitting device. An optical system configured to condense light to the image capturing device 1602 is formed on the lens 1601.

Glasses 1610 (smartglasses) according to one application example will be described with reference to FIG. 15B. The glasses 1610 include a control device 1612, and an image capturing device corresponding to the image capturing device 1602 and the light emitting device are mounted on the control device 1612. The image capturing device in the control device 1612 and an optical system configured to project light emitted from the light emitting device are formed in a lens 1611, and an image is projected to the lens 1611. The control device 1612 functions as a power supply that supplies electric power to the image capturing device and the light emitting device, and controls the operations of the image capturing device and the light emitting device. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device can include an image capturing device including a light receiving element, and control a displayed image based on the line-of-sight information of the user from the image capturing device. More specifically, the light emitting device decides a first visual field region at which the user is gazing and a second visual field region other than the first visual field region based on the line-of-sight information. The first visual field region and the second visual field region may be decided by the control device of the light emitting device, or those decided by an external control device may be received. In the display region of the light emitting device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device, the image capturing device, or an external device. If the external device holds the AI program, it is transmitted to the light emitting device via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-060969, filed Apr. 4, 2024, which is hereby incorporated by reference herein in its entirety.

What is claimed is:

1. A vapor deposition mask comprising:
a base material provided with a plurality of openings; and
a material layer that includes a first portion arranged on an inner wall of the base material facing one of the plurality of openings, and contains a material different from the base material,
wherein the material layer has a concave-convex shape in the first portion.

2. The vapor deposition mask according to claim 1, wherein
the mask has a first main surface to be faced with a vapor deposition target substrate, and a second main surface on an opposite side of the first main surface, and
the material layer includes a second portion that at least partially covers the second main surface.

3. The vapor deposition mask according to claim 2, wherein the material layer does not cover the first main surface.

4. The vapor deposition mask according to claim 1, wherein a ratio of a depth to a width of a concave portion of the concave-convex shape is not less than 1.

5. The vapor deposition mask according to claim 1, wherein
the material layer includes a first region and a second region arranged between the first region and the inner wall, and
the first region and the second region have different densities.

6. The vapor deposition mask according to claim 5, wherein the density of the second region is higher than the density of the first region.

7. The vapor deposition mask according to claim 1, wherein the material layer contains aluminum oxide crystals.

8. The vapor deposition mask according to claim 1, wherein the material layer has a higher etching rate with respect to a solution containing hydrochloric acid than the base material.

9. The vapor deposition mask according to claim 1, wherein the material layer contains at least one of aluminum oxide, titanium oxide, and an organic polymer.

10. The vapor deposition mask according to claim 1, wherein the base material contains silicon.

11. A manufacturing method of a vapor deposition mask, comprising:
preparing a base material provided with a plurality of openings;
forming a material layer including a first portion arranged on an inner wall of the base material facing one of the plurality of openings, and containing a material different from the base material; and
forming a concave-convex shape in the first portion of the material layer.

12. The method according to claim 11, wherein the material layer is formed using an atomic layer deposition method.

13. The method according to claim 11, wherein the preparing includes peeling off the material layer from a used vapor deposition mask.

14. The method according to claim 13, wherein the vapor deposition mask from which the material layer is peeled off is a vapor deposition mask that has been used for vapor deposition of a vapor deposition material.

15. The method according to claim 11, wherein the material layer contains aluminum oxide.

16. The method according to claim 13, wherein
the material layer contains aluminum oxide, and
the peeling off includes immersing the vapor deposition mask in a solution containing hydrochloric acid.

17. The method according to claim 16, wherein the vapor deposition mask immersed in the solution containing hydrochloric acid is a vapor deposition mask that has been used for vapor deposition of a vapor deposition material.

18. The method according to claim 15, wherein the forming the concave-convex shape includes immersing the material layer in warm water.

19. The method according to claim 18, wherein a temperature of the warm water is not less than 70° C. and not more than 100° C.

20. A manufacturing method of a light emitting device in which a plurality of pixels each including an organic layer including a light emitting layer are arranged, comprising
forming the organic layer by using a vapor deposition mask provided with a plurality of openings in a base material,
wherein
in the vapor deposition mask, a material layer that includes a first portion arranged on an inner wall of the base material facing one of the plurality of openings, and containing a material different from the base material is arranged, and
the material layer has a concave-convex shape in the first portion.
